(19) United States
(12) Patent Application Publication
(10) Pub. No.: US 2017/0346077 A1
(43) Pub. Date: Nov. 30, 2017

(54) CARBON COATING-TREATMENT APPARATUS, NEGATIVE ELECTRODE ACTIVE MATERIAL FOR NON-AQUEOUS ELECTROLYTE SECONDARY BATTERY AND METHOD FOR PRODUCING THE SAME, LITHIUM ION SECONDARY BATTERY AND ELECTROCHEMICAL CAPACITOR

(71) Applicant: SHIN-ETSU CHEMICAL CO., LTD., Tokyo (JP)

(72) Inventors: Hiromichi KAMO, Takasaki-shi (JP); Takakazu HIROSE, Annaka-shi (JP); Hiroki YOSHIKAWA, Takasaki-shi (JP)

(73) Assignee: SHIN-ETSU CHEMICAL CO., LTD., Tokyo (JP)

(21) Appl. No.: 15/541,651

(22) PCT Filed: Jan. 8, 2016
(86) PCT No.: PCT/JP2016/000073

§ 371 Date: Jul. 5, 2017

(30) Foreign Application Priority Data
Feb. 17, 2015 (JP) 2015-028211

(51) Int. Cl. H01M 4/36; H01M 4/48; H01G 11/86; H01G 11/46; H01G 11/30; H01G 11/06; C23C 16/44; H01M 10/0525; C01B 32/05

(52) U.S. Cl. CPC H01M 4/36; H01M 10/0525; H01M 4/48; H01G 11/86; C01B 32/05; H01G 11/30; H01G 11/06; C23C 16/44; H01G 11/46

(57) ABSTRACT

A carbon coating-treatment apparatus configured to introduce organic gas into the furnace tube through the gas introduction tube while stirring raw material particles introduced into the furnace tube with the stirring blade to coat the raw material particles with carbon coating, wherein the stirring blade is configured to have a proportion satisfying relation of V₂/V₁≧0.1, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from the central axis of the furnace tube, and R is the inner diameter of the furnace tube. A carbon coating-treatment apparatus that can sufficiently coat raw material particles with uniform carbon coating to produce particles having carbon coating in high productivity.

### TECHNICAL FIELD

The present invention relates to a carbon coating-treatment apparatus, a negative electrode active material for a non-aqueous electrolyte secondary battery and method for producing the same, a lithium ion secondary battery, and an electrochemical capacitor.

### BACKGROUND ART

With remarkable development of mobile electronic devices and communication devices, secondary batteries with higher energy density are strongly demanded recently in view of the economic efficiency, miniaturization and weight reduction of devices. As the secondary batteries that can fulfill this demand, lithium ion secondary batteries are exemplified. The battery characteristics of the lithium ion secondary battery largely changes depending on an electrode active material and so on to be employed. In the representative lithium ion secondary batteries that have been practically used presently, lithium cobalt oxide is used as the positive electrode active material, and graphite is used as the negative electrode active material. However, the battery capacity of such constituted lithium ion secondary batteries have been coming to the theoretical capacity, and it is difficult to largely improve the capacity in the future.

The capacity of the secondary batteries of this type can be improved by known methods such as use of a negative electrode material made of an oxide of V, Si, B, Zr or Sn, or a complex oxide thereof (See Patent Documents 1 and 2, for example); use of a negative electrode material made of a metal oxide subjected to melting and rapid cooling (See Patent Document 3, for example); use of a negative electrode material made of silicon oxide (See Patent Document 4, for example); and use of a negative electrode material made of Si₂N₂O and Ge₂N₂O (See Patent Document 5, for example). The negative electrode materials can be made conductive by known methods including mechanical alloying of SiO and graphite followed by carbonization (See Patent Document 6, for example); coating silicon particles with carbon layers by chemical vapor deposition (See Patent Document 7, for example); and coating silicon oxide particles with carbon layers by chemical vapor deposition (See Patent Document 8, for example).

Although these conventional methods increase the charge/discharge capacity and energy density to some extent, the increase is insufficient for market needs and the cycle performance fails to fulfill the needs. The conventional methods need to further improve the energy density and thus are not entirely satisfactory.

Patent Document 4 discloses use of a silicon oxide as a negative electrode active material for a lithium-ion secondary battery so as to obtain an electrode with high capacity. To the present inventor's knowledge, however, this method cannot achieve low irreversible capacity at initial charge/discharge and a practical level of cycle performance, so this method can be improved on.

The methods to provide a negative electrode active material with electric conductivity remain the following problems. The method in Patent Document 6 uses solid-state welding and thus cannot uniformly form carbon coating, resulting in insufficient electric conductivity. Although the method in Patent Document 7 enables the formation of a uniform carbon coating, this method uses Si as a negative electrode active material and thus reduces the cycle performance because the expansion and contraction of the material becomes too large at lithium insertion or extraction. This makes the material unsuited to practical use. The charge amount consequently needs to be limited to avoid this problem. In the method of Patent Document 8, the cycle performance is improved, but the capacity lowers gradually with an increase in charge/discharge cycles and to greatly reduce the capacity after given cycles due to insufficient fusion of a substrate and carbon coating, the structure of carbon coating, and precipitation of fine silicon crystals, which are still insufficient as a negative electrode material for a secondary battery. Patent Document 9 attempts to improve the battery capacity and the cycle performance by coating silicon oxide expressed by a general formula of SiOₓ with carbon coating by chemical vapor deposition to provide electric conductivity.

### CITATION LIST

### Patent Literature

Patent Document 1: Japanese Unexamined Patent Application publication (Kokai) No. H05-174818
Patent Document 2: Japanese Unexamined Patent Application publication (Kokai) No. H06-60867
Patent Document 3: Japanese Unexamined Patent Application publication (Kokai) No. H10-294112

### Patent Document 4: Japanese Patent No. 2997741

Patent Document 5: Japanese Unexamined Patent Application publication (Kokai) No. H11-102705
Patent Document 6: Japanese Unexamined Patent Application publication (Kokai) No. 2000-243396
Patent Document 7: Japanese Unexamined Patent Application publication (Kokai) No. 2000-215887
Patent Document 8: Japanese Unexamined Patent Application publication (Kokai) No. 2002-42806

### Patent Document 9: Japanese Patent No. 4171897

### SUMMARY OF INVENTION

### Problem to be Solved by the Invention

In carbon coating of particles as Patent Document 8 described above, it has never been established a method that can sufficiently coat the surfaces of raw material particles with uniform carbon coating in high productivity.

The present invention was accomplished in view of the above-described problems. It is an object of the present invention to provide a carbon coating-treatment apparatus that can sufficiently coat raw material particles with uniform carbon coating to produce particles having carbon coating in high productivity.

### Means for Solving Problem

To achieve the above-described objects, the present invention provides a carbon coating-treatment apparatus, comprising a furnace tube in which raw material particles are introduced, a stirring blade being configured to move in the furnace tube while being in contact with the raw material particles to stir the raw material particles, and a gas introduction tube to introduce organic gas into the furnace tube, and being configured to introduce the organic gas into the furnace tube through the gas introduction tube while stirring the raw material particles introduced into the furnace tube with the stirring blade to coat the raw material particles with carbon coating, wherein the stirring blade is configured to have a proportion satisfying a relation of V₂/V₁≧0.1, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from a central axis of the furnace tube, and R is an inner diameter of the furnace tube.

In such a carbon coating-treatment apparatus having a stirring blade, highly uniform coating can be formed, and the conversion ratio of organic gas to carbon is improved compared to those of a stationary apparatus without a stirring blade. With the stirring blade that moves to satisfy the relation of V₂/V₁≧0.1, it is possible to suppress adhesion of raw material particles to the stirring blade to suppress aggregation of the raw material particles, and to coat the whole surfaces of raw material particles with carbon coating. Accordingly, carbon coating treatment can be performed in higher productivity, and raw material particles can be coated with highly uniform carbon coating.

It is preferable that the proportion of V₂ to V₁ satisfy a relation of V₂/V₁≧0.3.

With such a proportion, adhesion of raw material particles to the stirring blade can be remarkably suppressed, and the carbon coating-treatment apparatus can coat the raw material particles with highly uniform carbon coating thereby.

It is preferable that the stirring blade have a stirring portion having a length, in a direction parallel to the central axis of the furnace tube, in a range of 30% or more and 99% or less of the length of the central axis of the furnace tube.

When the stirring portion exists in such a range, it is possible to stir raw material particles in a wider area in the furnace tube to coat the whole surfaces of raw material particles with carbon effectively and uniformly.

The stirring blade is preferably configured to move rotationally.

Such a stirring blade makes it possible to uniformly stir raw material particles in the furnace tube.

The stirring blade is preferably configured to rotate at a rotation rate of 10 rpm or more and 1000 rpm or less.

When the stirring blade moves at such a rotation rate, raw material particles are well stirred, and the whole surfaces thereof can be coated with carbon efficiently and uniformly.

The present invention also provides a method for producing a negative electrode active material for a non-aqueous electrolyte secondary battery, comprising: preparing particles containing one or more kind of element selected from Si and Ge as the raw material particles, and

coating surfaces of the raw material particles with carbon coating by using any one of the foregoing carbon coating-treatment apparatus to produce the negative electrode active material for a non-aqueous electrolyte secondary battery; thereby achieving the foregoing objects.

In carbon coating treatment, raw material particles containing the foregoing element(s) particularly tend to adhere to a stirring blade, thereby having been liable to lower the recovery rate of particles having desired carbon coating. In the inventive method for producing a negative electrode active material for a non-aqueous electrolyte secondary battery, however, it is possible to suppress adhesion of raw material particles to a stirring blade to produce negative electrode active material that fulfils properties on levels of market demands at low cost by using the inventive carbon coating-treatment apparatus.

In this method, the raw material particles preferably contain a particle containing silicon oxide shown by the general formula SiOₓ (0.5≦x<1.6).

By using such raw material particles, it is possible to produce a negative electrode active material for a non-aqueous electrolyte secondary battery that can improve the charge/discharge capacity. The inventive production method is more effectively used for carbon coating of raw material particles that contain silicon oxide as described above.

It is also preferable that the surfaces of the raw material particles be coated with carbon coating by chemical vapor deposition at 600° C. or more and 1300° C. or less in the organic gas.

The treatment temperature of 600° C. or more makes it possible to perform carbon coating efficiently and shorten the treatment time to bring high productivity. When the treatment temperature is 1300° C. or less, the whole surfaces of the raw material particle are uniformly coated with carbon coating without causing fusion and aggregation of the particles due to the chemical vapor deposition, thereby giving a negative electrode active material with good cycle performance. It also prevents unintended crystallization of silicon fine particles, when the raw material particles contain silicon, in the silicon-containing particles. Accordingly, it is possible to suppress expansion of the raw material particles, when they are used as a negative electrode active material for a lithium ion secondary battery, during the charging.

The present invention also provides a negative electrode active material for a non-aqueous electrolyte secondary battery produced by any one of the foregoing method for producing a negative electrode active material for a non-aqueous electrolyte secondary battery; thereby achieving the foregoing objects.

The negative electrode active material for a non-aqueous electrolyte secondary battery produced by the inventive production method can be a one provided with electric conductivity appropriately at low cost.

The present invention further provides a lithium ion secondary battery, comprising the foregoing negative electrode active material for a non-aqueous electrolyte secondary battery.

A high-quality and low-cost lithium ion secondary battery can be obtained by using the inventive negative electrode active material for a non-aqueous electrolyte secondary battery as described above.

The present invention further provides an electrochemical capacitor, comprising the foregoing negative electrode active material for a non-aqueous electrolyte secondary battery.

A high-quality and low-cost electrochemical capacitor can be obtained by using the inventive negative electrode active material for a non-aqueous electrolyte secondary battery as described above.

The present invention also provides a method for producing a negative electrode active material for a non-aqueous electrolyte secondary battery, comprising the steps of:

introducing raw material particles that contain a particle containing silicon oxide shown by the general formula SiOₓ (0.5≦x<1.6) into a furnace tube, and

coating surfaces of the raw material particles with carbon coating by introducing organic gas into the furnace tube while stirring the raw material particles introduced into the furnace tube by using a stirring blade provided with a portion to perform stirring having a length, in a direction parallel to a central axis of the furnace tube, in a range of 30% or more and 99% or less of the length of the central axis of the furnace tube to perform chemical vapor deposition at a temperature of 600° C. or more and 1300° C. or less;

wherein, the negative electrode active material for a non-aqueous electrolyte secondary battery is produced by coating the surfaces of the raw material particles with carbon coating in the coating step while stirring the raw material particles by moving the stirring blade so as to have a proportion satisfying a relation of V₂/V₁≦0.1, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from the central axis of the furnace tube, and R is an inner diameter of the furnace tube; thereby achieving the foregoing objects.

By moving the stirring blade so as to satisfy V₂/V₁≧0.1 as described above, carbon coating treatment can be performed in higher productivity, and can coat the raw material particles with highly uniform carbon coating. When the stirring portion is in the foregoing length, it is possible to stir raw material particles in a wider area of the interior of the furnace tube. The treatment temperature in the chemical vapor deposition of 600° C. or more makes it possible to perform carbon coating efficiently. When the treatment temperature is 1300° C. or less, the raw material particles do not cause fusion and aggregation due to the chemical vapor deposition. When the treatment temperature is 1300° C. or less, unintended crystallization of silicon fine particles is hard to proceed in the silicon-containing particles.

### Effect of Invention

The inventive carbon coating-treatment apparatus enable large-amount production of particles having carbon coating with desired quality. The inventive method for producing a negative electrode active material for a non-aqueous electrolyte secondary battery can coat the surfaces of raw material particles with high-quality carbon coating to improve the electric conductivity of the active material, and enables mass production of a negative electrode active material that fulfils properties on levels of market demands at low cost. The inventive negative electrode active material has good electric conductivity, with the high-quality carbon coating being formed. The inventive lithium ion secondary battery and electrochemical capacitor can be produced by using this negative electrode active material of the present invention.

### BRIEF DESCRIPTION OF DRAWINGS

FIG. 1 is a schematic diagram showing an example of the carbon coating-treatment apparatus of the present invention;

FIG. 2 is a diagram showing an outline of the region in the furnace tube except for a cylindrical region being in a distance of R/10 or less from the central axis of the furnace tube, where R is an inner diameter of the furnace tube, of the inventive carbon coating-treatment apparatus;

FIG. 3 are schematic diagrams illustrating the shapes of a stirring portion of the stirring blade;

FIG. 4 is a schematic sectional view of a negative electrode that contains the inventive negative electrode active material for a non-aqueous electrolyte secondary battery;

FIG. 5 is a diagram showing an example of the structure of the inventive lithium ion secondary battery (a laminate film type).

### DESCRIPTION OF EMBODIMENTS

Hereinafter, embodiments will be described with reference to the present invention, but the present invention is not limited thereto.

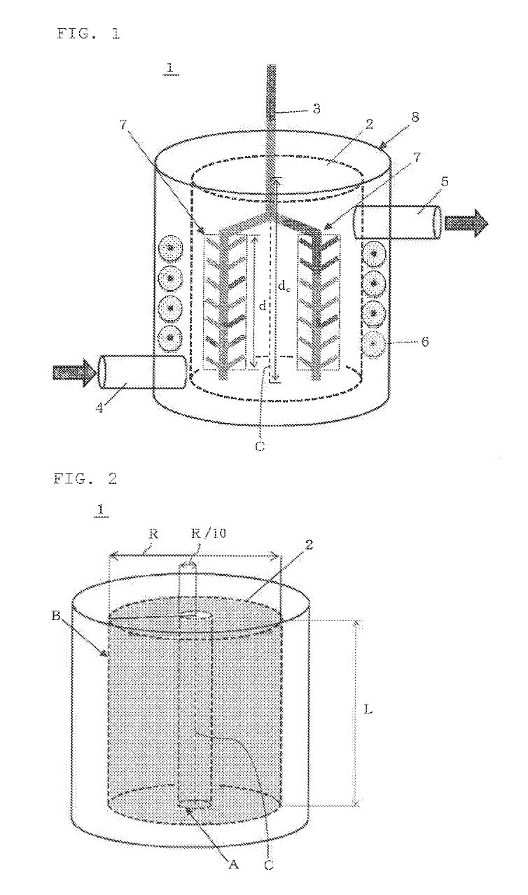

FIG. 1 is a schematic diagram showing an example of the inventive carbon coating-treatment apparatus. As shown in FIG. 1, the carbon coating-treatment apparatus 1 is mainly provided with the furnace tube 2 in which raw material particles are introduced to the interior thereof, the stirring blade 3 being configured to move in the furnace tube 2 while being in contact with the raw material particles to stir the raw material particles, the gas introduction tube 4 to introduce organic gas of the carbon coating source into the furnace tube 2, the exhaust tube 5 to exhaust from the furnace tube 2, the heater 6 to heat the furnace tube 2 to elevate the temperature of the interior of the furnace tube 2, etc. The foregoing furnace tube 2, the heater 6, etc. are housed in the chamber 8.

In such a carbon coating-treatment apparatus 1, the surfaces of raw material particles can be coated with carbon coating by introducing the organic gas into the furnace tube 2 through the gas introduction tube 4 while stirring the raw material particles introduced into the furnace tube 2 with the stirring blade 3, followed by increasing the temperature of the interior of the furnace tube 2 to a prescribed temperature and keeping thereat with the heater 6 while adjusting the exhaust amount from the exhaust tube 5.

In the inventive carbon coating-treatment apparatus 1, the stirring blade 3 is configured to have a proportion satisfying a relation of V₂/V₁≧0.1, where V₁ is a time-averaged volume of a portion of the stirring blade 3 positioned in the furnace tube 2, V₂ is a time-averaged volume of a portion of the stirring blade 3 positioned in a region of the interior of the furnace tube 2 except for a cylindrical region being in a distance of R/10 or less from the central axis of the furnace tube 2, where R is an inner diameter of the furnace tube 2, when stirring the raw material particles.

FIG. 2 illustrates an outline of the region of the interior of the furnace tube 2 except for a cylindrical region being in a distance of R/10 or less from the central axis of the furnace tube 2, where R is the inner diameter of the furnace tube 2, of the inventive carbon coating-treatment apparatus 1. Incidentally, FIG. 2 illustrates a case in which the furnace tube is in a cylindrical shape with the diameter being R as described above, and the height being L.

First, the cylindrical region being in a distance of R/10 or less from the central axis of the furnace tube 2 is the cylindrical region A in the furnace tube 2 with the distance from the central axis C of the furnace tube 2 being R/10 or less as shown in FIG. 2. Incidentally, the height of the cylindrical region A equals to L. In this case, the region of the interior of the furnace tube 2 except for this cylindrical region A is a region where the cylindrical region A is eliminated from the cylindrical region B with the diameter of the bottom of R and the height of L as shown in FIG. 2.

In the present invention, V₂ is defined as the time-averaged volume of a portion of the stirring blade 3 positioned in the foregoing region of the cylindrical region B except for the cylindrical region A when stirring raw material particles. Because the volume V₂ of the portion of the stirring blade 3 positioned in the region where the cylindrical region A is eliminated from the cylindrical region B can be varied in accordance with the passage of time in stirring of raw material particles, the average of the varying V₂ is adopted as the time-averaged volume V₂ of the stirring blade 3. The volume V₁ of the portion of the stirring blade 3 positioned in the furnace tube 2 can be varied in accordance with the passage of time in stirring of raw material particles, accordingly the average of the varying V₁ is adopted as the time-averaged volume V₁ of a portion of the stirring blade 3 positioned in the furnace tube 2 in the present invention.

In the present invention, the proportion of such defined time-averaged volume V₁ and time-averaged volume V₂ satisfies a relation of V₂/V₁≧0.1. It is more preferable that the proportion of the time-averaged volume V₁ and the time-averaged volume V₂ satisfy a relation of V₂/V₁≧0.3. With such a stirring blade, it is possible to suppress adhesion of raw material particles to the stirring blade 3. Accordingly, carbon coating treatment can be performed in higher productivity, and raw material particles can be coated with highly uniform carbon coating. By suppressing such adhesion of raw material particles to the stirring blade 3, aggregation of the raw material particles can be suppressed, and the whole surfaces of the raw material particles can be coated with carbon coating to improve the conversion ratio of organic gas to carbon. Accordingly, it is possible to form desired carbon coating efficiently to improve the productivity.

In the inventive carbon coating-treatment apparatus 1, the stirring blade 3 has the stirring portion 7 that preferably has a length, in the direction parallel to the central axis C of the furnace tube, in a range of 30% or more and 99% or less of the length of the central axis C of the furnace tube 2. The stirring portion 7 herein means a portion of the stirring blade 3 to directly contribute to the stirring of raw material particles. This is described with reference to FIG. 1 in such a way that the length “d” of the stirring portion 7 positioned in the furnace tube 2, in the direction parallel to the central axis C of the furnace tube, is preferably a length in the range of 30% or more and 99% or less of the length “d_{c}” of the central axis C of the interior of the furnace tube 2. That is, “d” preferably satisfies 0.3d_{c}≦d≦0.99d_{c}. With such a structure, it is possible to stir raw material particles in a wider area in the furnace tube 2 to coat the whole surfaces of raw material particles with carbon coating effectively and uniformly.

In the inventive carbon coating-treatment apparatus, it is also preferable that the stirring blade 3 be configured to move rotationally. It is further preferable that the stirring blade is configured to rotate at a rotation rate of 10 rpm or more and 1000 rpm or less. With such a stirring blade, it is possible to stir raw material particles uniformly in the furnace tube. When the stirring blade moves at the foregoing rotation rate, raw material particles are well stirred, and the whole surfaces of raw material particles can be coated efficiently and uniformly because the carbon coating is hard to be broken by the stirring blade 3.

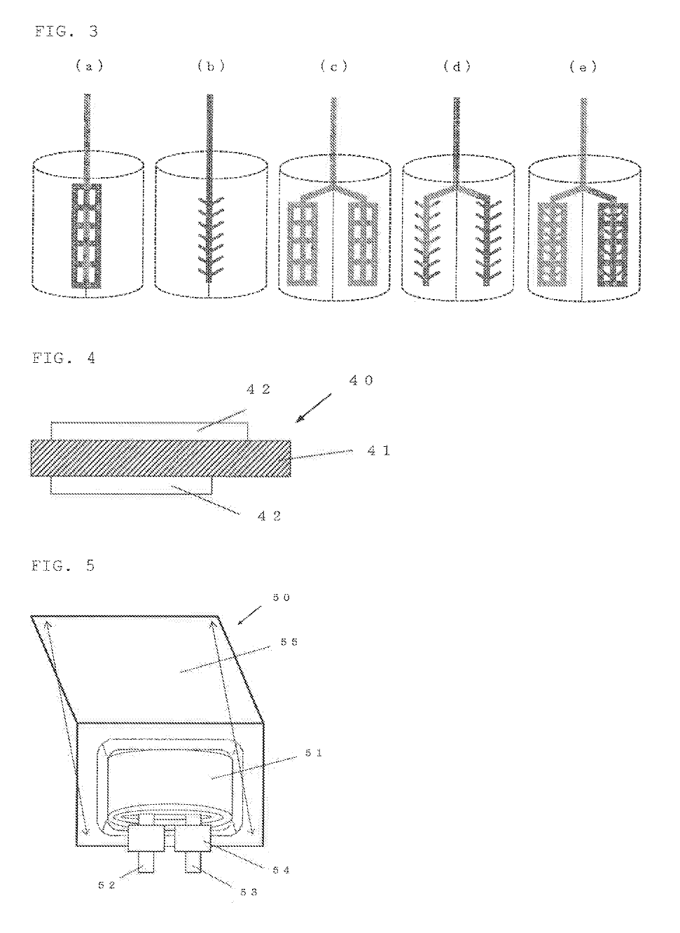

The shape of the stirring portion 7 of the stirring blade 3 is not particularly limited, and can be a shape shown in each of FIG. 3 (a) to (e), for example.

In FIG. 3 (a), the stirring portion 7 is in a lattice shape. In FIG. 3 (b), the stirring portion 7 is in a jet shape. The jet shape herein is a shape in which plural bars for stirring are extended from the shaft portion as shown in FIG. 3 (b). It is also possible to have one stirring portion 7 (uniaxial) as in FIGS. 3 (a) and (b), or to have two stirring portions 7 (biaxial) as in FIGS. 3 (c) to (e). It can be a jet/lattice combined shape in which the foregoing lattice shape and jet shape are combined as in FIG. 3 (e).

### [Method for Producing a Negative Electrode Active Material for a Non-Aqueous Electrolyte Secondary Battery]

Subsequently, the inventive method for producing a negative electrode active material for a non-aqueous electrolyte secondary battery will be described. In the method for producing a negative electrode active material for a non-aqueous electrolyte secondary battery of the present invention, it is possible to use the inventive carbon coating-treatment apparatus 1 as described above. Hereinafter, it will be described by reference to the carbon coating-treatment apparatus 1 shown in FIG. 1.

First, raw material particles to be coated with carbon is prepared, which can be particles containing one or more kind of element selected from Si and Ge. The inventive carbon coating-treatment apparatus 1 can also be used for carbon coating of raw material particles without containing Si and Ge, but is particularly suitable for carbon coating of particles that contain at least any of Si and Ge. In carbon coating treatment, raw material particles with good slipping such as carbon base active material are relatively hard to adhere to a stirring blade. On the other hand, raw material particles that contains an element such as Si or Ge particularly tend to adhere to a stirring blade, thereby causing lowering of the recovery rate of particles having desired carbon coating. However, by using the inventive carbon coating-treatment apparatus as in the inventive method for producing a negative electrode active material for a non-aqueous electrolyte secondary battery, it is possible to suppress adhesion of raw material particles to the stirring blade to produce a negative electrode active material that fulfils properties on levels of market demands at low cost.

As the particle that contains an Si element, it is possible to use silicon base material, including Si (metal silicon), a dispersed composite of silicon (Si) and silicon dioxide (SiO₂), silicon oxide such as SiOₓ (0.5≦x<1.6, particularly 1.0≦x<1.3), a particle having fine structure in which silicon fine particles are dispersed in a silicon compound (composite structure), and silicon suboxide (so called silicon oxide). It is particularly preferable that the raw material particles contain a particle containing silicon oxide shown by the general formula SiOₓ (0.5≦x<1.6) as the Si-containing particle.

As the raw material particles, it is also possible to prepare metal oxide without containing silicon shown by the formula of M1Oₐ (wherein, M1 is at least one kind of element selected from Ge, Sn, Pb, Bi, Sb, Zn, In, and Mg; “a” is a positive number of 0.1 to 4) or lithium composite oxide (which can contain silicon) shown by the formula of LiM2_{b}O_{c} (wherein, M2 is at least one kind of element selected from Ge, Sn, Pb, Bi, Sb, Zn, In, Mg, and Si; “b” is a positive number of 0.1 to 4; and “c” is a positive number of 0.1 to 8) in addition to the Si-containing particles described above. Illustrative examples thereof include GeO, GeO₂, SnO, SnO₂, Sn₂O₃, Bi₂O₃, Bi₂O₅, Sb₂O₃, Sb₂O₄, Sb₂Os, ZnO, In₂O, InO, In₂O₃, MgO, Li₂SiO₃, Li₄SiO₄, Li₂Si₃O₇, Li₂Si₂O₅, Li₈SiO₆, Li₆Si₂O₇, Li₄Ge₉O₇, Li₄Ge₉O₂, Li₅Ge₈O₁₉, Li₄Ge₅O₁₂, Li₅Ge₂O₇, Li₄GeO₄, Li₂Ge₇O₁₅, Li₂GeO₃, Li₂Ge₄O₉, Li₂SnO₃, Li₈SnO₆, Li₂PbO₃, Li₇SbO₅, LiSbO₃, Li₃SbO₄, Li₃BiO₅, Li₆BiO₆, LiBiO₂, Li₄Bi₆O₁₁, Li₆ZnO₄, Li₄ZnO₃, Li₂ZnO, LiInO₂, Li₃InO₃, and a nonstoichiometric compound thereof.

Particularly in case of using any of Si, a particle having composite structure in which silicon fine particles are dispersed in a silicon compound, and silicon oxide, which has large theoretical charge/discharge capacity, or a mixture of two or more of these; the charge/discharge capacity can be more improved, and the inventive production method can be used efficiently.

In these Si element-containing particles such as Si particles and particles having composite structure in which silicon fine particles are dispersed in a silicon compound, the average particle size is not particularly limited, but can be 0.01 μm or more and 50 μm or less, more preferably 0.1 μm or more and 20 μm or less, particularly 0.5 μm or more and 15 μm or less. When the average particle size is 0.01 μm or more, the material is hardly affected by surface oxidation because its surface area is prevented from becoming too large. This allows the material to keep the purity high and to maintain high charge/discharge capacity when the material is used as a negative electrode active material for a non-aqueous electrolyte secondary battery. The bulk density of this material can also be increased when the average particle size is 0.01 μm or more, resulting in an increase in charge/discharge capacity per volume. When the average particle size is 50 μm or less, a slurry obtained by mixing a negative electrode active material for a non-aqueous electrolyte secondary battery can readily be applied, for example, to a current collector when an electrode is produced. It is to be noted that the average particle size can be expressed by a volume average particle size by particle size distribution measurement using laser diffractometry.

In the particles having composite structure in which silicon fine particles are dispersed in a silicon compound, this silicon compound is preferably an inactive compound, and silicon dioxide is preferable in view of the easiness in production. In addition, it is preferable that the particles having composite structure in which silicon fine particles are dispersed in a silicon compound have the following properties (i) and (ii).

(i) The silicon fine particles (crystals) preferably has a particle size ranging from 1 to 500 nm, more preferably from 2 to 200 nm, further preferably from 2 nm to 20 nm, which is calculated by the Scherrer equation on the basis of a spread of a diffraction line of an observed diffraction peak attributable to Si (111) centered near 2θ=28.4° in X-ray diffraction (Cu-Kα) using copper as a counter negative electrode. When the silicon fine particles have a size of 1 nm or more, the charge/discharge capacity can be kept high. When this size is 500 nm or less, expansion and contraction at charging and discharging become small, and the cycle performance is improved. It is to be noted that the size of the silicon fine particles can also be measured by using photography of transmission electron microscope.
(ii) In measurement of a solid state NMR (²⁹Si-DDMAS), its spectra have a broad peak of silicon dioxide centered near −110 ppm, together with a characteristic peak of diamond crystal structure near −84 ppm. It is to be noted that these spectra differ markedly from those of normal silicon oxide (SiOₓ: x=1.0+α) to reveal that the structure is clearly different. The Si crystals are dispersed in an amorphous silicon dioxide, which can be observed with a transmission electron microscope. The amount of silicon fine particles (Si) dispersed in this silicon/silicon dioxide dispersion (Si/SiO₂) is preferably 2% by mass or more and 36% by mass or less, particularly from 10% by mass or more and 30% by mass or less. When the amount of this dispersed silicon is 2% by mass or more, the charge/discharge capacity can be kept high. When this amount is 36% by mass or less, good cycle performance can be obtained. A reference substance of a chemical shift in measurement of the solid NMR is hexamethylcyclotrisiloxane, which is a solid state at the measurement temperature.

It is to be noted that the particle having composite structure in which silicon fine particles are dispersed in a silicon compound (silicon composite powder) is a particle having a structure in which silicon fine crystals are dispersed in a silicon compound. A method of producing this particle is not particularly limited, provided its average diameter is preferably 0.01 μm or more and 50 μm or less as described above; the following method can be preferably used.

For example, it is possible to suitably adopt a method to disproportionate silicon oxide particles (powder) shown by the general formula SiOₓ (0.5≦x<1.6) by heat treatment in a temperature range of 900° C. or more and 1400° C. or less in an inert atmosphere.

Incidentally, the silicon oxide in this case generally refers to amorphous silicon oxide obtained by heating a mixture of silicon dioxide and metal silicon to generate silicon monoxide gas, followed by cooling to precipitate the same. The silicon oxide powder is shown by the general formula SiOₓ, and the lower limit of the average particle size is preferably 0.01 μm or more, more preferably 0.1 μm or more, particularly 0.5 μm or more. The upper limit of the average particle size is preferably 50 μm or less, more preferably 20 μm or less, particularly 15 μm or less. The BET specific surface area is preferably 0.1 m²/g or more, more preferably 0.2 m²/g or more, with the upper limit being preferably 30 m²/g, more preferably 20 m²/g. The range of “x” is 0.5≦x<1.6, more preferably 0.8≦x<1.3, particularly 0.8≦x≦1.0.

When the silicon oxide powder has an average particle size and a BET specific surface area in the foregoing range, it is easy to obtain silicon composite powder having a desired average particle size and BET specific surface area. The SiOₓ powder with the value of “x” is 0.5 or more brings good cycle performance. With the value of “x” being less than 1.6, the ratio of inert SiO₂ becomes small when disproportionation reaction is performed by heat treatment, and higher charge/discharge capacity can be obtained when used for a lithium ion secondary battery.

The disproportionation of the silicon oxide becomes efficient when the heat treatment temperature is 900° C. or more, which proceeds the disproportionation efficiently and can form fine cells of Si (silicon fine crystals) in a short period. When the heat treatment temperature is 1400° C. or less, the silicon dioxide portion in the silicon oxide is hard to be structured, thereby preventing the movement of lithium ions from being hindered without causing risk of lowering the function as a lithium ion secondary battery. A preferable range of the heat treatment is from 1000° C. to 1300° C., more preferable range of the heat treatment is from 1000° C. to 1200° C.

The foregoing disproportionation treatment can be performed in an inert gas atmosphere by using a reaction apparatus having a heating mechanism. The reaction apparatus is not particularly limited, and it is possible to appropriately select a furnace that can process by a continuous method or a batch method, specifically a fluidized-bed reaction furnace, a rotary furnace, a vertical moving-bed reaction furnace, a tunnel furnace, a batch type furnace, a rotary kiln, etc. in accordance with the object. In this case, it is possible to use one-component gas that is inert at the foregoing temperature such as Ar, He, H₂, and N₂; or mixed gas thereof as the disproportionation treatment gas. In the inventive method for producing a negative electrode active material for a non-aqueous electrolyte secondary battery, the disproportionation treatment may be performed simultaneously with carbon coating. When the disproportionation treatment is performed simultaneously with carbon coating, the inventive carbon coating-treatment apparatus can be used appropriately. The foregoing raw material particles can be prepared, but the raw material particles are not limited to these materials naturally.

Subsequently, the raw material particles can be coated with carbon coating by using the inventive carbon coating-treatment apparatus 1 as in FIG. 1.

On this occasion, it is preferable that the surfaces of the raw material particles be coated with carbon coating by chemical vapor deposition at 600° C. or more and 1300° C. or less in the organic gas. It is more preferable to set the treatment temperature in this chemical vapor deposition to 900° C. or more and 1100° C. or less.

The treatment temperature of 600° C. or more makes it possible to perform carbon coating efficiently and shorten the treatment time to bring high productivity. When the treatment temperature is 1300° C. or less, the surfaces of the raw material particle are uniformly coated with carbon coating without causing fusion and aggregation of the particles due to the chemical vapor deposition, and a negative electrode active material having good cycle performance can be obtained. It also prevents unintended crystallization of silicon fine particles in the silicon-containing particles. When the particles are used as a negative electrode active material for a lithium ion secondary battery, the expansion can be suppressed during the charging. Herein, the treatment temperature means the maximum temperature setting in a carbon coating-treatment apparatus, and in many cases, it corresponds to the temperature at the central portion of the furnace tube 2 in case of fluidized-bed having the stirring blade 3 as in the inventive carbon coating-treatment apparatus 1 shown in FIG. 1.

The treatment time is appropriately selected in accordance with the targeted carbon coating amount, the treatment temperature, the concentration (flow rate) of organic gas, the amount of organic gas to be introduced, etc. It is generally efficient economically, however, to set the residence time at the maximum temperature region to 1 to 20 hours, particularly 2 to 10 hours.

As an organic material that can be used as a raw material to generate organic gas to be supplied to the furnace tube 2 in the present invention, it is possible to select the one that can be thermally decomposed at the foregoing heat treatment temperature to generate carbon, particularly in a non-oxidizing atmosphere. Illustrative examples thereof include a hydrocarbon such as methane, ethane, ethylene, acetylene, propane, propylene, butane, butene, pentane, isobutane, hexane, and a mixture thereof; and an aromatic hydrocarbon of a monocycle to a tricycle such as benzene, toluene, xylene, styrene, ethylbenzene, diphenylmethane, naphthalene, phenol, cresol, nitrobenzene, chlorobenzene, indene, cumarone, pyridine, anthracene, phenanthrene, and a mixture thereof. A gas light oil, a creosote oil, an anthracene oil, a naphtha-cracked tar oil obtained by a tar distillation process, and a mixture thereof can also be used.

Subsequently, the properties of the negative electrode active material produced by coating the surfaces of raw material particles with carbon coating by the inventive production method will be described. The carbon coating amount of a negative electrode active material is not particularly limited, but it is preferably 0.3% by mass or more and 40% by mass or less, more preferably 0.5% by mass or more and 30% by mass or less, further preferably 2% by mass or more and 20% by mass or less based on the total amount of the raw material particles and the carbon coatings. When the carbon coating amount is 0.3% by mass or more, sufficient electric conductivity can be preserved, and the cycle performance becomes good when it is used for a non-aqueous electrolyte secondary battery. When the carbon coating amount is 40% by mass or less, the ratio of carbon in the negative electrode material becomes properly. By applying this to raw material particles, particularly silicon-containing particles such as silicon oxide particles shown by the general formula SiOₓ (0.5≦x<1.6), to produce a negative electrode material, higher charge/discharge capacity can be obtained when the particles are used for a non-aqueous electrolyte secondary battery.

The coverage of carbon coating of a negative electrode active material, that is, the ratio of carbon coating amount to the surface of the negative electrode active material can be evaluated by the following Raman spectrum analysis. This will be described by exemplifying the case that employs a silicon compound as raw material particles. It is possible to determine the ratio of a portion attributable to silicon on the surfaces of raw material particles and a portion of a carbon material having a graphite structure on the basis of Raman spectrum obtained by micro-Raman analysis (i.e., Raman spectrometry). That is, silicon shows a peak near 500 cm⁻¹ at a Raman shift, and graphite shows a sharp peak near 1580 cm⁻¹ at a Raman shift. On the basis of the ratio of these peak intensities I₅₀₀/I₁₅₈₀, it is possible to obtain a simplified value corresponding to the coverage of carbon coating. In this case, it is preferable that the intensity ratio I₅₀₀/I₁₅₈₀ be 1.3 or less, more preferably 1.0 or less. When the intensity ratio I₅₀₀/I₁₅₈₀ is 1.3 or less, it can be considered that the surfaces of raw material particles are sufficiently coated with carbon coating, and it is possible to obtain good initial efficiency and capacity retention ratio.

By using the inventive negative electrode active material for a non-aqueous electrolyte secondary battery, it is possible to produce a lithium ion secondary battery and an electrochemical capacitor that are high-quality and low cost. The lithium ion secondary battery, for example, is characterized by using the negative electrode active material. Other materials used for the negative electrode, materials of the positive electrode, electrolyte, and a separator, as well as the shape of a battery are not limited. For example, a usable positive electrode active material includes transition metal oxide and chalcogen compounds such as LiCoO₂, LiNiO₂, LiMn₂O₄, V₂O₅, MnO₂, TiS₂, and MoS₂. As the electrolyte, a non-aqueous solution containing lithium salt such as lithium perchlorate can be used, for example; and propylene carbonate, ethylene carbonate, dimethoxyethane, γ-butyrolactone, 2-methyltetrahydrofuran, and combination of two or more kinds thereof can be used as the non-aqueous solvent. It is also possible to use another non-aqueous electrolyte or a solid electrolyte.

In producing a negative electrode by using a negative electrode active material for a non-aqueous electrolyte secondary battery produced by the present invention, a conductive agent such as graphite can be added to the negative electrode active material. In this case, the conductive agent is not particularly limited as far as being an electron conductive material that does not cause decomposition or degradation in the structured battery. Illustrative examples thereof include metal powder and metal fiber of Al, Ti, Fe, Ni, Cu, Zn, Ag, Sn, Si, etc., as well as graphite such as natural graphite, synthetic graphite, various coke powders, mesophase carbon, vapor growth carbon fiber, pitch-based carbon fiber, PAN-based carbon fiber, baked materials of various resins, etc.

### [Method for Producing a Negative Electrode]

As a specific method for producing a negative electrode, particles of negative electrode active material, which contain the foregoing particles forming carbon coating mixed with carbon base active material in accordance with needs, are mixed with other materials such as a binder (a negative electrode binder) and a conductive additive to form a negative electrode mixture, and then an organic solvent or water is added to form slurry.

Subsequently, this slurry of the negative electrode mixture is applied onto the surface of a negative electrode current collector, followed by drying to form a negative electrode active material layer. At this stage, it is possible to perform heat press and so on in accordance with needs. An example of a negative electrode produced by such a method is shown in FIG. 4. In the negative electrode 40 shown in FIG. 4, negative electrode active material layers 42 are formed on the both sides of the negative electrode current collector 41. The negative electrode active material layer 42 can be formed on one side of the negative electrode current collector 41.

### <Lithium Ion Secondary Battery>

Then, a laminate film type lithium ion secondary battery will be described as a specific example of the non-aqueous electrolyte secondary battery using the inventive negative electrode described above.

### [Configuration of Laminate Film Type Lithium Ion Secondary Battery]

The laminate film type lithium ion secondary battery 50 shown in FIG. 5 includes the wound electrode body 51 interposed between the sheet-shaped outer parts 55. This wound body is formed by winding a positive electrode, a negative electrode, and a separator disposed between these electrodes. The electrode body may also be composed of a laminated part of the positive and negative electrodes, and a separator disposed between these electrodes. The electrode bodies of both types have the positive electrode lead 52 attached to the positive electrode and the negative electrode lead 53 attached to the negative electrode. The outermost circumference of the electrode bodies is protected by a protecting tape.

The positive electrode lead and the negative electrode lead, for example, extend from the interior of the outer parts 55 toward the exterior in one direction. The positive electrode lead 52 is made of, for example, an electric conductive material such as aluminum; the negative electrode lead 53 is made of, for example, an electric conductive material such as nickel or copper.

An example of the outer part 55 is a laminate film composed of a fusion-bond layer, a metallic layer, and a surface protecting layer stacked in this order. Two laminate films are fusion-bonded or stuck with an adhesive at the outer edge of their fusion-bond layers such that each fusion-bond layer faces the electrode body 51. The fusion-bond layer may be, for example, a film such as a polyethylene or polypropylene film; the metallic layer may be aluminum foil; the protecting layer may be nylon.

The space between the outer parts 55 and the positive and negative electrode leads is filled with the close adhesion films 54 to prevent air from entering therein. Exemplary materials of the close adhesion films include polyethylene, polypropylene, and polyolefin resin.

### [Positive Electrode]

The positive electrode is provided with positive electrode active material layers on both sides or on one side of a positive current collector, for example, as a negative electrode.

The positive electrode current collector is formed by electric conductive material such as aluminum.

The positive electrode active material layer contains any one or more of positive electrode material which can absorb and release lithium ions, and may contain other materials such as a positive electrode binder, a conductive assistant agent for a positive electrode, and a dispersing agent according to the design.

As the positive electrode material, a lithium-containing compound is desirable. Illustrative examples of this lithium-containing compound includes composite oxides consist of lithium and a transition metal element or phosphate compounds containing lithium and a transition metal element. Among these positive electrode materials described, compounds containing one or more of nickel, iron, manganese, cobalt are preferred. These positive electrode materials are represented by chemical formulae such as LiₓM₁₁O₂ or Li_{y}M₁₂PO₄. In the formulae, M₁₁ and M₁₂ represent at least one kind of transition metal elements; the values “x” and “y” are generally represented by 0.05≦x≦1.10, 0.05≦y≦1.10, although they represent different values depending on a charge/discharge state of a battery.

As the composite oxides containing lithium and a transition metal element, for example, composite oxide of lithium and cobalt (LiₓCoO₂), composite oxide of lithium and nickel (LiₓNiO₂), lithium-nickel-cobalt composite oxide, etc. are illustrated. As the lithium-nickel-cobalt composite oxide, lithium-nickel-cobalt-aluminum composite oxide (NCA) and lithium-nickel-cobalt-manganese composite oxide (NCM) are illustrated.

As the phosphate compounds containing lithium and a transition metal element, for example, lithium iron phosphate compound (LiFePO₄), lithium iron manganese phosphate compound (LiFe₁₋ᵤMnᵤPO₄ (0<u<1)) are illustrated. By using positive electrode material described above, high battery capacity together with excellent cycle characteristics can be obtained.

### [Negative Electrode]

The negative electrode has a constitution same as the negative electrode for a lithium ion secondary battery, and has negative electrode active material layers on both sides of a current collector, for example. The negative electrode is preferred to have larger negative charge capacity compared to the electric capacity obtained from the positive electrode active material agent (a charge capacity as a battery). This makes it possible to suppress deposition of lithium metal on the negative electrode.

The positive electrode active material layer is provided on a part of both surfaces of a positive electrode current collector, and the negative electrode active material layers are also provided on a part of both surfaces of a negative electrode current collector. In this case, the negative electrode active material layer provided on the negative electrode current collector, for example, has a region which does not corresponds to the positive electrode active material layer to be faced. This intends to perform stabilized battery design.

The above region where the negative electrode active material layer and the positive electrode active material layer do not face each other is hardly influenced by charging and discharging. Therefore the state of a negative electrode active material layer is kept intact as just after the formation, which makes it possible to evaluate the composition of the negative electrode active material and the like accurately with good reproducibility without depending on the existence or nonexistence of charging and discharging.

### [Separator]

The separator separates the positive electrode and the negative electrode, prevents short circuit current due to contact of these electrodes, and passes lithium ions therethrough. This separator may be made of, for example, a porous film of synthetic resin or ceramics, or two or more stacked porous films. Examples of the synthetic resin include polytetrafluoroethylene, polypropylene, and polyethylene.

### [Electrolytic Solution]

A part of the active material layer or the separator is impregnated with liquid electrolyte (electrolytic solution). This electrolytic solution is composed of electrolyte salt dissolved in a solvent and may contain other materials such as additives.

The solvent may be, for example, a non-aqueous solvent. Examples of the non-aqueous solvent include ethylene carbonate, propylene carbonate, butylene carbonate, dimethyl carbonate, diethyl carbonate, ethyl methyl carbonate, methyl propyl carbonate, 1,2-dimethoxyethane, and tetrahydrofuran. Among these, at least one of ethylene carbonate, propylene carbonate, dimethyl carbonate, diethyl carbonate, and ethyl methyl carbonate is preferably used. The reason is that such solvent enables better battery characteristics. In this case, it is also possible to obtain better performances by combining high-viscosity solvent such as ethylene carbonate, propylene carbonate and low-viscosity solvent such as dimethyl carbonate, ethyl methyl carbonate, diethyl carbonate, for such a solvent improves the dissociation of electrolyte salt and ionic mobility.

For an alloyed negative electrode, the solvent preferably contains at least one of halogenated chain carbonate ester and halogenated cyclic carbonate ester. Such a solvent enables the negative electrode active material to be coated with a stable coating at discharging and particularly charging. The halogenated chain carbonate ester is chain carbonate ester having halogen as a constitutive element (that is, at least one hydrogen is substituted by halogen). And the halogenated cyclic carbonate ester is cyclic carbonate ester having halogen as a constitutive element (that is, at least one hydrogen is substituted by halogen).

The halogen is preferably, but not limited to, fluorine, for fluorine enables the formation of better coating than other halogens do. A larger number of halogens is better, for a more stable coating can be obtained which reduces a decomposition reaction of an electrolyte.

Examples of the halogenated chain carbonate ester include fluoromethyl methyl carbonate, difluoromethyl methyl carbonate. Examples of the halogenated cyclic carbonate ester include 4-fluoro-1,3-dioxolane-2-one, 4,5-difluoro-1,3-dioxolane-2-one.

The solvent preferably contains cyclic carbonate ester having an unsaturated carbon bond as an additive, for this enables the formation of a stable coating on a negative electrode surface at charging and discharging as well as the inhibition of a decomposition reaction of an electrolytic solution. Examples of the cyclic carbonate ester having an unsaturated carbon bond include vinylene carbonate and vinyl ethylene carbonate.

In addition, the solvent preferably contains sultone (cyclic sulfonic ester) as an additive, for this enables improvement in chemical stability of a battery. Examples of the sultone include propane sultone and propene sultone.

In addition, the solvent preferably contains acid anhydride, for this enables improvement in chemical stability of a battery. The acid anhydride may be, for example, propane disulfonic acid anhydride.

The electrolyte salt may contain, for example, at least one light metal salt such as lithium salt. Examples of the lithium salt include lithium hexafluorophosphate (LiPF₆) and lithium tetrafluoroborate (LiBF₄).

The content of the electrolyte salt is preferably in the range from 0.5 mol/kg to 2.5 mol/kg based on the solvent. The reason is that this content enables high ionic conductivity.

### [Method for Producing a Laminate Film Type Secondary Battery]

Firstly, a positive electrode is produced with the above positive electrode material as follows. A positive electrode mixture is created by mixing the positive electrode active material with as necessary a positive electrode binder, a positive electrode conductive additive, and other materials, and dispersed in an organic solvent to form slurry of the positive electrode mixture. This mixture slurry is then applied to a positive electrode current collector with a coating apparatus such as a die coater having a knife roll or a die head, and dried by hot air to obtain a positive electrode active material layer. The positive electrode active material layer is finally compressed with, for example, a roll press. The compression may be performed under heating. The compression may be repeated plural times.

A negative electrode active material layer is then formed on a negative electrode current collector to produce a negative electrode through the same procedure as in the above production of the positive electrode for a lithium-ion secondary battery.

When the positive electrode and the negative electrode are produced, the active material layers are formed on both faces of the positive and negative electrode current collector. In both the electrodes, the length of these active material applied on the faces may differ from one another (see FIG. 4).

Then, an electrolytic solution is prepared. With ultrasonic welding, the positive electrode lead is attached to the positive electrode current collector and the negative electrode lead is attached to the negative electrode current collector. The positive and negative electrodes and the separator interposed therebetween are stacked or wound to produce the wound electrode body and a protecting tape is stuck to the outermost circumference of the body. The electrode body is flattened. The film-shaped outer part is folded in half to interpose the wound electrode body therebetween. The outer edge of the half parts is stuck to one another by heat sealing such that one of the four sides is opened to enter the wound electrode body therefrom. The close adhesion films are inserted between the outer part and the positive and negative electrode leads. The above prepared electrolytic solution is introduced from the open side in a prescribed amount to perform the impregnation of the electrolytic solution under a vacuum. The open side is then stuck by vacuum heat sealing. In this way, a laminate film type secondary battery can be produced.

The inventive non-aqueous electrolyte secondary battery, such as the laminate film type secondary battery produced in the above, preferably has a negative electrode utilization factor of 93% or more and 99% or less at charging and discharging. The secondary battery having a negative electrode utilization factor of 93% or more prevents reduction in the initial charge/discharge efficiency and greatly improves the battery capacity; one having a negative electrode utilization factor of 99% or less prevents the precipitation of Li, thereby ensuring safety.

### EXAMPLE

Hereinafter, the present invention will be more specifically described by showing Examples of the present invention and Comparative Examples, but the present invention is not limited to these Examples.

### Example 1-1

As raw material particles, 1000 g of silicon oxide particles with the average particle size of 5 μm shown by the general formula SiOₓ (x=1.02) were prepared and introduced into the furnace tube of the inventive carbon coating-treatment apparatus shown in FIG. 1. Provided that the stirring blade used therein had a biaxial stirring portion in a jet/lattice combined shape as shown in FIG. 3 (e). While rotating this stirring blade at 200 rpm, organic gas in which methane gas and nitrogen gas had been mixed in the volume ratio of 4:1 was introduced into the furnace tube at the rate of 1 NL/min, followed by elevating the temperature over 2 hours and holding the temperature (the holding temperature was set to 1018° C.) for 8 hours to perform chemical vapor deposition. In this case, the proportion of V₂/V₁ was 0.9, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from the central axis of the furnace tube.

After lowering the temperature in the furnace tube, the content was classified with a sieve having an opening of 50 μm to give silicon oxide particles having carbon coating. At this stage, the recovery rate was calculated by dividing the mass of the silicon oxide particles having carbon coating left under the sieve by the mass of prepared raw material particles before carbon coating. This makes it possible to evaluate the ratio of particles that could form desired carbon coating without causing aggregation in the furnace tube based on the raw material particles. In addition, the carbon coating amount (mass %) was calculated on the silicon oxide particles having carbon coating left under the sieve. The recovery rate and the carbon coating amount are shown in Table 1.

Subsequently, a lithium ion secondary battery was produced as follows in order to evaluate the battery characteristics when the produced silicon oxide particles having carbon coating is used as a negative electrode active material.

First, a positive electrode was produced. As a positive electrode active material, 95 parts by mass of lithium-cobalt composite oxide (LiCoO₂), 2.5 parts by mass of a positive electrode conductive additive (acetylene black), and 2.5 parts by mass of a positive electrode binder (polyvinylidene fluoride, PVDF) were mixed to form a positive electrode mixture. The positive electrode mixture was then dispersed into an organic solvent (N-methyl-2-pyrrolidone, NMP) to form a paste-form slurry. Subsequently, the slurry was applied onto the both faces of a positive electrode current collector with a coating apparatus having a die head, and subjected to drying with a hot air drier. This case employed a positive electrode current collector with the thickness of 15 μm. Finally, compression molding was performed with a roll press.

Next, a negative electrode was produced. The produced silicon base active material as a negative electrode active material was mixed with a conductive additive (acetylene black) and polyacrylic acid in a dry mass ratio of 85:5:10, followed by dilution with pure water to form negative electrode mixture slurry.

As this negative electrode current collector, electrolytic copper foil (thickness=15 μm) was used. Finally, the negative electrode mixture slurry was applied onto the negative electrode current collector, and subjected to drying at 100° C. for 1 hour under a vacuum. The deposited amount of the negative electrode active material layer per unit area on a face of the negative electrode after drying (referred to as an area density) was 3 mg/cm².

Subsequently, solvents (4-fluoro-1,3-dioxolane-2-one (FEC), ethylene carbonate (EC), and dimethyl carbonate (DMC)) were mixed, and electrolyte salt (lithium hexafluorophosphate (LiPF₆)) was dissolved to prepare an electrolytic solution. In this case, the solvent composition was set to FEC:EC:DMC=10:20:70 in a volume ratio, and the content of the electrolyte salt was set to 1.2 mol/kg based on the solvent.

Then, a secondary battery was assembled as follows. First, an aluminum lead was attached to one end of the positive electrode current collector with ultrasonic welding, and a nickel lead was welded to the negative electrode current collector. Subsequently, the positive electrode, a separator, the negative electrode, and a separator were laminated in this order, and wound in the longitudinal direction to produce a wound electrode body. The end of the winding was fixed with a PET protecting tape. The separator used herein was a laminate film with 12 μm in which a film mainly composed of porous polyethylene was sandwiched by films mainly composed of porous polypropylene. Subsequently, the electrode body was interposed between outer parts, and then the outer edge of the outer parts was stuck to one another by heat sealing such that one of the four sides was opened to enter the electrode body therefrom. The outer part was an aluminum laminate film in which a nylon film, aluminum foil, and a polypropylene film were laminated. Then, the electrolytic solution was introduced from the open side to perform the impregnation under a vacuum. The open side was then stuck by heat sealing.

Subsequently, the cycle performance and the initial efficiency were evaluated on the secondary battery thus produced.

The cycle performance was investigated in the following manner: First, two cycles of charging and discharging were performed at 25° C. to stabilize the battery and the discharge capacity in the second cycle was measured. Next, the cycle of charging and discharging was repeated until the total number of cycles reached 50 cycles and the discharge capacity was measured every cycle. Finally, a capacity retention rate was calculated by dividing the discharge capacity in the 50-th cycle by the discharge capacity in the second cycle. The cycle conditions were as follows: The secondary batteries were charged with a constant current density of 2.5 mA/cm² until the voltage reached 4.2 V. After this voltage reached 4.2 V, the charging was continued while the current density became 0.25 mA/cm² at a constant voltage of 4.2 V. The batteries were then discharged with a constant current density of 2.5 mA/cm² until the voltage reached 2.5 V.

The initial efficiency was calculated by the following expression:

Initial efficiency (%)=(initial discharge capacity/initial charge capacity)×100.

It is to be noted that the atmosphere and the temperature were set to the same as in the investigation of the cycle performances, and the charge/discharge condition was set to 0.2 times that of the investigation of the cycle performances. That is, the battery was charged at a constant current density of 0.5 mA/cm² until the voltage reached 4.2 V, and after the voltage had reached 4.2 V, the battery was charged at a constant voltage of 4.2 V until the current density reached 0.05 mA/cm². The battery was then discharged at a constant current density of 0.5 mA/cm² until the voltage reached 2.5 V.

### Example 1-2 to Example 1-6

Silicon oxide powders having carbon coating were produced in the same manner as in Example 1-1 except for changing the shape of the stirring portion of the stirring blade to any of the shapes shown in FIG. 3 (a) to (d), and changing the V₂/V₁ value to values shown in Table 1. On the produced silicon oxide powders having carbon coating, the recovery rates and the carbon coating amounts were calculated in the same manner as in Example 1-1. In addition, secondary batteries were prepared, and the cycle performances and the initial efficiencies were evaluated in the same manner as in Example 1-1.

### Comparative Example 1-1

Silicon oxide powder having carbon coating was produced in the same manner as in Example 1-1 except for using a conventional carbon coating-treatment apparatus having no stirring blade to perform carbon coating without stirring the raw material particles during the coating. On the produced silicon oxide powder having carbon coating, the recovery rate and the carbon coating amount were calculated in the same manner as in Example 1-1. In addition, secondary battery was prepared, and the cycle performance and the initial efficiency were evaluated in the same manner as in Example 1-1.

### Comparative Example 1-2

Silicon oxide powder having carbon coating was produced in the same manner as in Example 1-1 except for setting the V₂/V₁ value to 0.05. On the produced silicon oxide powder having carbon coating, the recovery rate and the carbon coating amount were calculated in the same manner as in Example 1-1. In addition, secondary battery was prepared, and the cycle performance and the initial efficiency were evaluated in the same manner as in Example 1-1.

The results of Example 1-1 to Example 1-6, Comparative Example 1-1, and Comparative Example 1-2 are shown in Table 1.

TABLE 1

| | | | | Carbon |
|---|---|---|---|---|
| | | | Recovery | coating |
| | Structure of portion to | | rate | amount |
| | perform stirring | V₂/V₁ | (mass %) | (mass %) |
| Comparative | No stirring portion | — | 10 | 2.1 |
| Example 1-1 | | | | |
| Comparative | (e) jet/lattice | 0.05 | 15 | 2.5 |
| Example 1-2 | combined shape, biaxial | | | |
| Example 1-1 | (e) jet/lattice | 0.90 | 96 | 5.3 |
| | combined shape, biaxial | | | |
| Example 1-2 | (a) lattice shape | 0.50 | 42 | 3.5 |
| Example 1-3 | (b) jet shape | 0.25 | 39 | 3.2 |
| Example 1-4 | (c) lattice shape, | 0.75 | 90 | 5.3 |
| | biaxial | | | |
| Example 1-5 | (d) jet shape, biaxial | 0.83 | 87 | 5.2 |
| Example 1-6 | (e) jet/lattice ombined | 0.10 | 36 | 3.3 |
| | shape, biaxial | | | |

As can be seen from Table 1, Examples 1-1 to 1-6, satisfying the relation of V₂/V₁≧0.1, showed higher recovery rates, larger amounts of carbon coating, and better battery characteristics compared to those of Comparative Examples. It was also found that the biaxial stirring blades showed remarkably higher recovery rates and gave particles that could form a desired carbon coating in larger rate compared to the uniaxial stirring blades. On the other hand, in Comparative Examples, the recovery rates and the carbon coating ratios were extremely low, which revealed that particles having desired carbon coating cannot be produced in large quantities.

### Example 2-1 to Example 2-7

Silicon oxide powders having carbon coating were produced in the same manner as in Example 1-1 except for changing the holding temperature in the furnace tube, that is, the treatment temperature at the chemical vapor deposition to values shown in Table 2. On the produced silicon oxide powders having carbon coating, the recovery rates and the carbon coating amounts were calculated in the same manner as in Example 1-1. In addition, secondary batteries were prepared, and the cycle performances and the initial efficiencies were evaluated in the same manner as in Example 1-1.

The results of Example 2-1 to Example 2-7 are shown in Table 2.

TABLE 2

| | Holding | | | Carbon | | Re- |
|---|---|---|---|---|---|---|
| | tem- | | Recovery | coating | Initial | tention |
| | perature | V₂/ | rate | amount | efficiency | rate |
| | (° C.) | V₁ | (mass %) | (mass %) | (%) | (%) |
| Example | 605 | 0.90 | 99 | 0.7 | 60.2 | 82.7 |
| 2-1 | | | | | | |
| Example | 708 | 0.90 | 99 | 0.9 | 63.5 | 83.1 |
| 2-2 | | | | | | |
| Example | 810 | 0.90 | 98 | 2.1 | 65.2 | 83.5 |
| 2-3 | | | | | | |
| Example | 912 | 0.90 | 97 | 3.7 | 67.3 | 84.6 |
| 2-4 | | | | | | |
| Example | 1018 | 0.90 | 96 | 5.3 | 69.8 | 84.3 |
| 1-1 | | | | | | |
| Example | 1140 | 0.90 | 91 | 8.6 | 70.2 | 81.9 |
| 2-5 | | | | | | |
| Example | 1290 | 0.90 | 82 | 11.3 | 71.8 | 81.1 |
| 2-6 | | | | | | |
| Example | 1385 | 0.90 | 76 | 16.1 | 74.2 | 71.3 |
| 2-7 | | | | | | |

The treatment temperature of 600° C. or more was suitable in the chemical vapor deposition. When the treatment temperature was higher, the organic gas was sufficiently decomposed, and the raw material particles could be provided with sufficient electric conductivity. Accordingly, the initial battery efficiency was increased as the treatment temperature got higher. On the other hand, when the treatment temperature was 1300° C. or less, unintended disproportionation of silicon oxide did not proceed, and the retention rate could be kept high.

### Example 3-1 to Example 3-6

Silicon oxide powders having carbon coating were produced in the same manner as in Example 1-1 except for changing the rotation rate of the stirring blade to values shown in Table 3. The coverages of carbon coating of silicon oxide powder having carbon coating, that is, the carbon coating ratios on the surface of the silicon oxide were evaluated by using peak intensity ratio I₅₀₀/I₁₅₈₀ obtained by Raman spectrum analyses.

On the produced silicon oxide powders having carbon coating, the recovery rates and the carbon coating amounts were calculated in the same manner as in Example 1-1. In Example 3-1 to Example 3-6, secondary batteries were prepared, and the cycle performances and the initial efficiencies were evaluated in the same manner as in Example 1-1.

The results of Example 3-1 to Example 3-6 are shown in Table 3.

TABLE 3

| | | | | Carbon | |
|---|---|---|---|---|---|
| | Rotation | | Recovery | coating | |
| | rate | | rate | amount | |
| | (rpm) | V₂/V₁ | (mass %) | (mass %) | I₅₀₀/I₁₅₈₀ |
| Example | 5 | 0.90 | 72 | 4.1 | 1.20 |
| 3-1 | | | | | |
| Example | 10 | 0.90 | 95 | 4.9 | 0.91 |
| 3-2 | | | | | |
| Example | 50 | 0.90 | 95 | 5.2 | 0.89 |
| 3-3 | | | | | |
| Example | 200 | 0.90 | 96 | 5.3 | 0.85 |
| 1-1 | | | | | |
| Example | 500 | 0.90 | 97 | 5.2 | 0.90 |
| 3-4 | | | | | |
| Example | 1000 | 0.90 | 98 | 5.2 | 1.01 |
| 3-5 | | | | | |
| Example | 3000 | 0.90 | 98 | 5.3 | 1.30 |
| 3-6 | | | | | |

As shown in Table 3, when the rotation rate of the working portion of the stirring mechanism was changed, the rotation rate of 10 rpm or more improved the recovery rate and the carbon coating amount. It was also found that the rotation rate of 1000 rpm or less brought small I₅₀₀/I₁₅₈₀ value in Raman spectrum as well as small silicon rate and high carbon rate on the surfaces of the raw material particles. That is, it was found that the coverage by carbon coating were excellent. This is probably due to slight breaking of carbon coating with the stirring blade.

### Example 4-1 to Example 4-4

Silicon oxide powders having carbon coating were produced in the same manner as in Example 1-1 except for changing the ratio of the length of the stirring portion of the stirring blade to the length of the central axis of the furnace tube, each of the length being in the direction parallel to the central axis of the furnace tube, to values described in Table 4. It is to be noted that the positions of the lower end and the upper end of the stirring portion in Table 4 show the values of the coordinate system directed to the central axis of the furnace tube, with the origin 0 being the coordinate of the lower end, and the coordinate L being the upper end of the furnace tube. That is, the length of the central axis is L in this case. The length of the stirring portion in the direction parallel to the central axis of the furnace tube corresponds to a value of difference between the upper end position and the lower end position of the stirring portion.

On the produced silicon oxide powders having carbon coating, the recovery rates and the carbon coating amounts were calculated in the game manner as in Example 1-1. In addition, secondary batteries were prepared, and the cycle performances and the initial efficiencies were evaluated in the same manner as in Example 1-1.

The results of Example 4-1 to Example 4-4 are shown in Table 4.

TABLE 4

| | | | Ratio of | | | |
|---|---|---|---|---|---|---|
| | Extent of stirring | | length | | | |
| | portion | | of | | | Carbon |
| | Lower | Upper | strirring | | Recovery | coating |
| | end | end | portion | | rate | amount |
| | position | position | (%) | V₂/V₁ | (mass %) | (mass %) |
| Example | 0.4 L | 0.6 L | 20 | 0.90 | 61 | 2.9 |
| 4-1 | | | | | | |
| Example | 0.65 L | 0.9 L | 25 | 0.90 | 58 | 2.4 |
| 4-2 | | | | | | |
| Example | 0.1 L | 0.25 L | 15 | 0.90 | 67 | 3.2 |
| 4-3 | | | | | | |
| Example | 0.3 L | 0.7 L | 40 | 0.90 | 91 | 5.0 |
| 4-4 | | | | | | |
| Example | 0.1 L | 0.95 L | 85 | 0.90 | 96 | 5.3 |
| 1-1 | | | | | | |

As shown in Table 4, when the positions of stirring portion were changed, the recovery rates and the carbon coating amounts were improved as enlarging the ratio of the length of the stirring portion of the stirring blade in the direction parallel to the central axis of the furnace tube relative to the length of the central axis of the furnace tube, with the ratio being 30% or more and 99% or less. This is because the stirring occurs in a region where the stirring blade exists, and raw material particles are uniformly stirred as the region gets wider.

### Example 5-1 to Example 5-5

Raw material particles were coated with carbon coating in the same manner as in Example 1-1 except for changing the kind of raw material particles as described in Table 5. In table 5, D₅₀ is a volume average particle size by particle size distribution measurement using laser diffractometry. It is to be noted that Example 5-3 employed a mixture of Sn and Co in the mass ratio of 1:1 as the raw material particles, which were coated with carbon coating at the holding temperature of 700° C. for the holding time of 10 hours. On the produced particles, the carbon coating amounts were calculated in the same manner as in Example 1-1. In addition, secondary batteries were prepared, and the cycle performances and the initial efficiencies were evaluated in the same manner as in Example 1-1.

The results of Example 5-1 to Example 5-5 are shown in Table 5.

TABLE 5

| | | | | Carbon | | |
|---|---|---|---|---|---|---|
| | Raw | | | coating | Initial | Retention |
| | material | D₅₀ | V₂/ | amount | efficiency | rate |
| | particle | (μm) | V₁ | (mass %) | (%) | (%) |
| Example | Si | 4.4 | 0.90 | 4.6 | 85.5 | 67.4 |
| 5-1 | | | | | | |
| Example | Ge | 4.1 | 0.90 | 4.3 | 85.1 | 65.1 |
| 5-2 | | | | | | |
| Example | Sn/Co | 4.8 | 0.90 | 2.1 | 86.2 | 63.4 |
| 5-3 | (1:1) | | | | | |
| Example | SiOₓ | 5.1 | 0.90 | 5.1 | 71.4 | 81.7 |
| 5-4 | (x = 0.55) | | | | | |
| Example | SiOₓ | 5.2 | 0.90 | 5.3 | 69.8 | 84.3 |
| 1-1 | (x = 0.95) | | | | | |
| Example | SiOₓ | 5.1 | 0.90 | 5.1 | 67.7 | 84.7 |
| 5-5 | (x = 1.2) | | | | | |

As shown in Table 5, each battery retention rate and initial efficiency was varied depending on the variation of raw material particles. Particularly, the material of SiOₓ (x=0.95) showed most balanced battery characteristics. This is probably due to the amount of irreversible component to trap lithium, which becomes appropriate when the value of “x” (amount of oxygen) is 0.9 or more and 1.1 or less to give good initial efficiency. In addition, Si showed higher retention rate than Ge and Sn/Co.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. A carbon coating-treatment apparatus, comprising a furnace tube in which raw material particles are introduced, a stirring blade being configured to move in the furnace tube while being in contact with the raw material particles to stir the raw material particles, and a gas introduction tube to introduce organic gas into the furnace tube, and being configured to introduce the organic gas into the furnace tube through the gas introduction tube while stirring the raw material particles introduced into the furnace tube with the stirring blade to coat the raw material particles with carbon coating,
wherein the stirring blade is configured to have a proportion satisfying a relation of V₂/V₁≧0.1, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from a central axis of the furnace tube, and R is an inner diameter of the furnace tube.

14. The carbon coating-treatment apparatus according to claim 13, wherein the proportion of V₂ to V₁ satisfies a relation of V₂/V₁≧0.3.

15. The carbon coating-treatment apparatus according to claim 13, wherein the stirring blade has a portion to perform stirring having a length, in a direction parallel to the central axis of the furnace tube, in a range of 30% or more and 99% or less of the length of the central axis of the furnace tube.

16. The carbon coating-treatment apparatus according to claim 14, wherein the stirring blade has a portion to perform stirring having a length, in a direction parallel to the central axis of the furnace tube, in a range of 30% or more and 99% or less of the length of the central axis of the furnace tube.

17. The carbon coating-treatment apparatus according to claim 13, wherein the stirring blade is configured to move rotationally.

18. The carbon coating-treatment apparatus according to claim 14, wherein the stirring blade is configured to move rotationally.

19. The carbon coating-treatment apparatus according to claim 15, wherein the stirring blade is configured to move rotationally.

20. The carbon coating-treatment apparatus according to claim 16, wherein the stirring blade is configured to move rotationally.

21. The carbon coating-treatment apparatus according to claim 17, wherein the stirring blade is configured to rotate at a rotation rate of 10 rpm or more and 1000 rpm or less.

22. The carbon coating-treatment apparatus according to claim 18, wherein the stirring blade is configured to rotate at a rotation rate of 10 rpm or more and 1000 rpm or less.

23. The carbon coating-treatment apparatus according to claim 19, wherein the stirring blade is configured to rotate at a rotation rate of 10 rpm or more and 1000 rpm or less.

24. The carbon coating-treatment apparatus according to claim 20, wherein the stirring blade is configured to rotate at a rotation rate of 10 rpm or more and 1000 rpm or less.

25. A method for producing a negative electrode active material for a non-aqueous electrolyte secondary battery, comprising:
preparing particles containing one or more kind of element selected from Si and Ge as the raw material particles, and
coating surfaces of the raw material particles with carbon coating by using the carbon coating-treatment apparatus according to claim 13 to produce the negative electrode active material for a non-aqueous electrolyte secondary battery.

26. A method for producing a negative electrode active material for a non-aqueous electrolyte secondary battery, comprising:
preparing particles containing one or more kind of element selected from Si and Ge as the raw material particles, and
coating surfaces of the raw material particles with carbon coating by using the carbon coating-treatment apparatus according to claim 24 to produce the negative electrode active material for a non-aqueous electrolyte secondary battery.

27. A method for producing a negative electrode active material for a non-aqueous electrolyte secondary battery according to claim 25, wherein the raw material particles contain a particle containing silicon oxide shown by the general formula SiOₓ (0.5≦x<1.6).

28. A method for producing a negative electrode active material for a non-aqueous electrolyte secondary battery according to claim 25, wherein the surfaces of the raw material particles are coated with carbon coating by chemical vapor deposition at 600° C. or more and 1300° C. or less in the organic gas.

29. A negative electrode active material for a non-aqueous electrolyte secondary battery produced by the method for producing a negative electrode active material for a non-aqueous electrolyte secondary battery according to claim 25.

30. A lithium ion secondary battery, comprising the negative electrode active material for a non-aqueous electrolyte secondary battery according to claim 29.

31. An electrochemical capacitor, comprising the negative electrode active material for a non-aqueous electrolyte secondary battery according to claim 29.

32. A method for producing a negative electrode active material for a non-aqueous electrolyte secondary battery, comprising the steps of:
introducing raw material particles that contain a particle containing silicon oxide shown by the general formula SiOₓ (0.5≦x<1.6) into a furnace tube, and
coating surfaces of the raw material particles with carbon coating by introducing organic gas into the furnace tube while stirring the raw material particles introduced into the furnace tube by using a stirring blade provided with a portion to perform stirring having a length, in a direction parallel to a central axis of the furnace tube, in a range of 30% or more and 99% or less of the length of the central axis of the furnace tube to perform chemical vapor deposition at a temperature of 600° C. or more and 1300° C. or less;
wherein, the negative electrode active material for a non-aqueous electrolyte secondary battery is produced by coating the surfaces of the raw material particles with carbon coating in the coating step while stirring the raw material particles by moving the stirring blade so as to have a proportion satisfying a relation of V₂/V₁≧0.1, where V₁ is a time-averaged volume of a portion of the stirring blade positioned in the furnace tube, V₂ is a time-averaged volume of a portion of the stirring blade positioned in a region of the furnace tube except for a cylindrical region being in a distance of R/10 or less from the central axis of the furnace tube, and R is an inner diameter of the furnace tube.
